(19) United States
(12) Patent Application Publication
(10) Pub. No.: US 2008/0284325 A1
(43) Pub. Date: Nov. 20, 2008

(54) Organic electroluminescent device and method for preparing the same

(75) Inventors: Jeoung-Kwen Noh, Daejeon Metropolitan City (KR); Young-Chul Lee, Daejeon Metropolitan City (KR); Min-Soo Kang, Daejeon Metropolitan City (KR)

Correspondence Address: MCKENNA LONG & ALDRIDGE LLP, 1900 K STREET, NW, WASHINGTON, DC, 20006, US

(73) Assignee: LG CHEM, LTD., Seoul (KR)

(21) Appl. No.: 12/149,747

(22) Filed: May 7, 2008

Related U.S. Application Data
(63) Continuation of application No. PCT/KR2006/004620, filed on Nov. 7, 2006.

(30) Foreign Application Priority Data
Nov. 7, 2005 (KR) 10-2005-0105812

(51) Int. Cl. H01L 51/54; H01J 9/02

(52) U.S. Cl. 313/504; 445/24

(57) ABSTRACT

The present invention relates to an organic electroluminescent device comprising a substrate, a cathode, at least two organic material layers comprising a light-emitting layer, and an anode in the sequentially laminated form, in which the organic material layers comprise an organic material layer comprising a compound having a functional group selected from the group consisting of an imidazole group, an oxazole group and a thiazole group between the cathode and the light-emitting layer. The organic electroluminescent device according to the present invention comprises an organic material layer comprising a compound having a functional group selected from the group consisting of an imidazole group, an oxazole group and a thiazole group between a cathode and a light-emitting layer, thus having an improved electron injection characteristic to provide an organic electroluminescent device of an inverted structure operating at a low voltage.

### TECHNICAL FIELD

The present invention relates to an organic electroluminescent device and a method for preparing the same. More particularly, the present invention relates to an organic electroluminescent device of an inverted structure operating at a low driving voltage, and a method for preparing the same.

This application claims priority benefits from Korean Patent Application No. 10-2005-0105812, filed on Nov. 7, 2005, the entire contents of which are fully incorporated herein by reference.

### BACKGROUND ART

Organic electroluminescent devices (OLED) are generally composed of two electrodes (an anode and a cathode) and at least one organic material layer located between these electrodes. When voltage is applied between the two electrodes of the organic electroluminescent device, holes and electrons are injected into the organic material layer from the anode and cathode, respectively, and are recombined in the organic material layer to form excitons. In turn, when these excitons decay to their ground state, photons corresponding to the energy difference are emitted. By this principle, the organic electroluminescent devices generate visible ray, and they are used in the fabrication of information display devices and illumination devices.

The organic electroluminescent devices are classified into three types: a bottom emission type in which light produced in the organic material layer is emitted in the direction of a substrate; a top emission type in which the light is emitted in direction opposite the substrate; and a both-side emission type in which the light is emitted in both the direction of the substrate and the direction opposite the substrate.

In passive matrix organic electroluminescent device (PMOLED) displays, an anode and a cathode perpendicularly cross each other, and the area of the crossing point acts as a pixel. Thus, the bottom emission and top emission types have no great difference in effective display area ratios (aperture ratios).

However, active matrix organic electroluminescent device (AMOLED) displays include thin-film transistors (TFrs) as switching devices for driving the respective pixels. Because the fabrication of these TFTs generally requires a high-temperature process (at least several hundred ° C.), a TFT array required for the driving of organic electroluminescent devices is formed on a glass substrate before the deposition of electrodes and organic material layers. In this regard, the glass substrate having the TFT array formed thereon is defined as a backplane. When the active matrix organic electroluminescent device displays having this backplane are fabricated to have the bottom emission structure, a portion of light emitted toward the substrate is blocked by the TFT array, resulting in a reduction in the effective display aperture ratio. This problem becomes more severe when pluralities of TFTs are given to one pixel in order to fabricate more elaborate displays. The bottom-emission structure is known to have the display aperture ratio of less than 40%. When WXGA (Wide Extended Graphics Array) is applied to 14″ grade using TFT, the display aperture ratio should be equal to or less than 20%. The reduction of the display aperture ratio affects the electric power consumed for driving and life time of the organic electroluminescent device. For this reason, the active matrix organic electroluminescent devices need to be fabricated to have the top emission structure.

In the top emission type or both-side emission type organic electroluminescent devices, an electrode located on the opposite side of the substrate without making contact with the substrate must be transparent in the visible ray region. In the organic electroluminescent devices, a conductive oxide film made of, for example, indium zinc oxide (IZO) or indium tin oxide (ITO), is used as the transparent electrode. However, this conductive oxide film has a very high work function of generally more than 4.5 eV. For this reason, if the cathode is made of this oxide film, the injection of electrons from the cathode into the organic material layer becomes difficult, resulting in a great increase in the operating voltage of the organic electroluminescent devices and deteriorations in important device characteristics, such as light emission efficiency. The top emission or both-side emission type organic electroluminescent devices need to be fabricated to have the so-called “inverted structure” formed by the sequential lamination of the substrate, the cathode, the organic material layer and the anode.

An electron injection characteristic from a cathode to an electron transport layer in a regular organic electroluminescent device, is improved by depositing a thin LiF layer, which helps the injection of electrons, between the electron transport layer and the cathode. However, in this case, the electron injection characteristic is improved only when the method is used in a device in which the cathode is used as a top contact electrode, while the electron injection characteristic is very poor when the method is used in a device having an inverted structure in which the cathode is used as a bottom contact electrode.

“An effective cathode structure for inverted top-emitting organic electroluminescent device,” Applied Physics Letters, Volume 85, September 2004, p. 2469, describes an attempt to improve the electron injection characteristic through a structure having a very thin Alq3-LiF-Al layer between a cathode and an electron transport layer.

However, the structure has a disadvantage that the fabricating process is very complicated. In addition, “Efficient bottom cathodes for organic electroluminescent device,” Applied Physics Letters, Volume 85, August 2004, p. 837, describes an attempt to improve the electron injection characteristic by depositing a thin Al layer between a metal-halide layer (NaF, CsF, KF) and an electron transport layer. However, the method also has a problem in the process because a new layer must be used. WO03/83958 describes an organic electroluminescent device of an inverted structure having an charge transport layer n-doped (Bphen:Li) between an cathode and an light-emitting layer. However, the organic electroluminescent device also has a problem in the complicated process for fabricating due to application of the n-dopping process.

Meanwhile, in a process of fabricating the organic electroluminescent device with the above-described inverted structure, if the anode located on the organic material layer is formed of a transparent conductive oxide film, such as IZO or ITO, by the use of resistive heating evaporation, the resistive heating evaporation will cause the collapse of the inherent chemical composition ratio of the oxide due to, for example, thermal decomposition during a thermal evaporation procedure. This will result in the loss of characteristics, such as electrical conductivity and visible ray permeability. For this reason, the resistive heating evaporation cannot be used in the deposition of the conductive oxide film, and in most cases, techniques, such as plasma sputtering, are now used.

However, if the electrode is formed on the organic material layer by techniques such as sputtering, the organic material layer can be damaged due to, for example, electrically charged particles present in plasma used in the sputtering process. The damage of the organic material layer generates the reduction of characteristics for injecting and transporting electrons or holes and for emitting light.

To avoid damage to the organic material layer, which can occur when forming an electrode on the organic material layer, for example, methods for lowering RF power or DC voltage in an RF or DC sputtering process to reduce the number and mean kinetic energy of atoms incident from a sputtering target onto the substrate of the organic electroluminescent device, thus reducing sputtering damage to the organic material layer, and methods for increasing the distance between the sputtering target and the substrate of the organic electroluminescent device to enhance the opportunity of the collisions between atoms, incident to the substrate of the organic electroluminescent device from a sputtering target, and sputtering gases (e.g., Ar), thus intentionally reducing the kinetic energy of the atoms.

However, as most of the above-described methods result in a very low deposition rate, the processing time of the sputtering step becomes very long, resulting in a significant reduction in productivity throughout a batch process for fabricating the organic electroluminescent device. Furthermore, even in an instance when the sputtering process has a low deposition rate as described above, the possibility of particles having high kinetic energy reaching the surface of the organic material layer still exists, and thus, it is difficult to effectively prevent sputtering damage to the organic material layer.

“Transparent organic light emitting devices,” Applied Physics Letters, May 1996, Volume 68, p. 2606, describes a method of forming an anode and organic material layers on a substrate, and then forming a thin layer of mixed metal film of Mg:Ag having excellent electron injection performance thereon, and lastly, forming a cathode using ITO by sputtering deposition thereon, as shown in FIG. 1. However, the Mg:Ag metal film has shortcomings in that the metal film is lower in visible ray permeability than ITO or IZO and also its process control is somewhat complicated.

“A metal-free cathode for organic semiconductor devices,” Applied Physics Letters, Volume 72, April 1998, p. 2138, describes an organic electroluminescent device having a structure formed by the sequential lamination of a substrate, an anode, an organic material layer and a cathode, where a CuPc layer, relatively resistant to sputtering, is deposited between the organic material layer and the cathode in order to prevent sputtering damage to the organic material layer, which is caused by the deposition of the cathode, as shown in FIG. 2. However, while CuPc is generally used to form a hole injection layer, in the above literature, CuPc serves as an electron injection layer in a state damaged by sputtering, between the organic material layer and the cathode in the organic electroluminescent device with a structure formed by the sequential lamination of the substrate, the anode, the organic material layer and the cathode. This deteriorates device characteristics, such as the charge injection characteristic and electric current efficiency of the organic electroluminescent device. Furthermore, CuPc has large light absorption in the visible ray region, and thus, increasing the thickness of the CuPc film leads to rapid deterioration of the device performance.

“Interface engineering in preparation of organic surface emitting diodes,” Applied Physics Letters, Volume 74, May 1999, p. 3209, describes an attempt to improve the low electron injection characteristic of the CuPc layer by depositing a second electron transport layer (e.g., Li thin film) between an electron transport layer and the CuPc layer, as shown in FIG. 3. However, this method for preventing sputtering damage has problems in that an additional thin metallic film is required and process control also becomes difficult.

In the process for fabricating an organic electroluminescent device of an inverted structure, methods to prevent the decrease in the electron injection characteristic due to contact related problems between the cathode and organic materials and the damage of the organic material layer when forming the anode, are required.

### DISCLOSURE OF INVENTION

### Technical Problem

The present inventors have found a group of compounds that can act as materials for an electron transport layer in an organic electroluminescent device of an inverted structure to improve the electron injection characteristic from a bottom cathode to an electron transport layer, thereby providing the organic electroluminescent device of the inverted structure that can operate in low voltage. In addition, the present inventors have found a group of compounds that can act as materials of a buffer layer to prevent damage to an organic material layer, which can occur when forming the anode on the organic material layer, without deterioration of light emission characteristic.

Therefore, it is an objective of the present invention to provide an organic electroluminescent device of an inverted structure that operate at a low voltage and have an improved electron injection characteristic by using a compound having a functional group selected from the group consisting of an imidazole group, an oxazole group and a thiazole group, and a method for fabricating the device. It is an another objective of the present invention to provide an organic electroluminescent device of an inverted structure comprising a buffer layer to prevent damage of an organic material layer, which can occur when forming the anode on the organic material layer. It is an another objective of the present invention to provide an organic light-emitting devide of a top emission type or a both-side emission type based on the above device of the inverted structure.

### Technical Solution

The present invention provides an organic electroluminescent device having an inverted structure, characterized in that it comprises a substrate, a cathode, at least two organic material layers including a light-emitting layer, and an anode in the sequentially laminated form, in which the organic material layers include an organic material layer, comprising a compound having a functional group selected from the group consisting of an imidazole group, an oxazole group and a thiazole group, positioned between the cathode and the light-emitting layer. The compound having a functional group selected from the group consisting of an imidazole group, an oxazole group and a thiazole group includes the compound of the following formula 1 or 2:

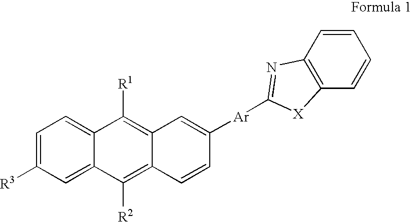

wherein, R¹ and R² may be the same or different from each other, and are each respectively selected from the group consisting of hydrogen, aliphatic hydrocarbons of 1-20 carbon atoms, aromatic rings and aromatic heterocyclic rings; Ar is selected from the group consisting of aromatic rings and aromatic heterocyclic rings; R³ is selected from the group consisting of hydrogen, aliphatic hydrocarbons having 1-6 carbon atoms, aromatic rings and aromatic heterocyclic rings; and X is selected from the group consisting of O, S and NR¹¹ wherein R¹¹ is selected from the group consisting of hydrogen, aliphatic hydrocarbons of 1-7 carbon atoms, aromatic rings and aromatic heterocyclic rings, provided that both of R¹ and R² are not hydrogen at the same time, and

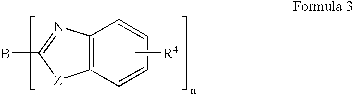

wherein Z is O, S or NR²²; R⁴ and R²² are respectively hydrogen, alkyl of 1-24 carbon atoms, aryl or hetero-atom substituted aryl of 5-20 carbon atoms, halogen atoms, or alkylene or alkylene comprising a hetero-atom necessary to complete a fused ring with a benzazole ring; B is a linkage unit consisting of alkylene, arylene, substituted alkylene, or substituted arylene, which conjugatedly or unconjugately connects the multiple benzazoles together; and n is an integer from 3 to 8.

### ADVANTAGEOUS EFFECTS

The organic electroluminescent device according to the present invention comprises an organic material layer comprising a compound having a functional group selected from the group consisting of an imidazole group, an oxazole group and thiazole group between the cathode and the light-emitting layer, thus having an improved electron injection characteristic to provide an organic electroluminescent device of an inverted structure operating at a low voltage. In addition, the organic electroluminescent device according to the present invention comprises a buffer layer between the light-emitting layer and the anode, thus preventing damage to the organic material layer, which can occur when forming the anode on the organic material layer in a process of fabricating the organic electroluminescent device of the inverted structure.

### BRIEF DESCRIPTION OF THE DRAWINGS

The above and other objects, features and advantages of the present invention will be more clearly understood from the following detailed description taken in conjunction with the accompanying drawings, in which:

FIG. 1 illustrates the structure of the prior organic electroluminescent device formed by sequentially laminating a substrate, an anode, organic material layers and a cathode (ITO), in which an Mg:Ag layer is applied between one of the organic material layers and the ITO cathode;

FIG. 2 illustrates the structure of the prior organic electroluminescent device formed by sequentially laminating a substrate, an anode, organic material layers and a cathode (ITO), in which a CuPc layer is applied between one of the organic material layers and the ITO cathode;

FIG. 3 illustrates the structure of the prior organic electroluminescent device shown in FIG. 2, in which a Li thin film (electron injection layer) is laminated as an organic material layer in contact with the CuPc layer in the electroluminescent device;

FIG. 4 illustrates the structure of a top emission type organic electroluminescent device according to the present invention;

FIG. 5 illustrates the structure of a both-side emission type organic electroluminescent device according to the present invention;

FIG. 6 illustrates a structure of a device having a symmetrical structure consisting of Al-LiF-electron transport layer-LiF-Al fabricated in Example 1.

FIG. 7 is a graphic diagram showing a forward voltage-current characteristic and reverse voltage-current characteristic by electrons in the device having a symmetrical structure fabricated in Example 1.

FIG. 8 is a graphic diagram showing a change in the reverse voltage-current (leakage current) characteristic of an organic electroluminescent device as a function of the thickness of the inventive buffer layer;

FIG. 9 is a graphic diagram showing a change in the forward voltage-current characteristic of an organic electroluminescent device as a function of the thickness of the inventive buffer layer;

FIG. 10 is a graphic diagram showing the luminous intensity-current density characteristic of an organic electroluminescent device as a function of the thickness of the inventive buffer layer; and

FIG. 11 is a graphic diagram showing the luminance efficiency-current density characteristic of an organic electroluminescent device as a function of the thickness of the inventive buffer layer.

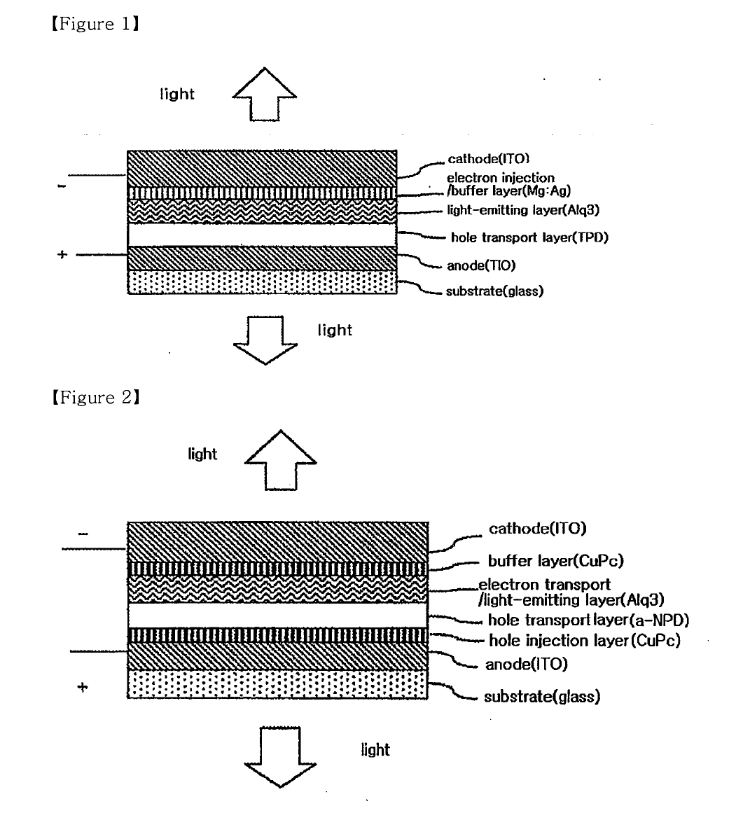

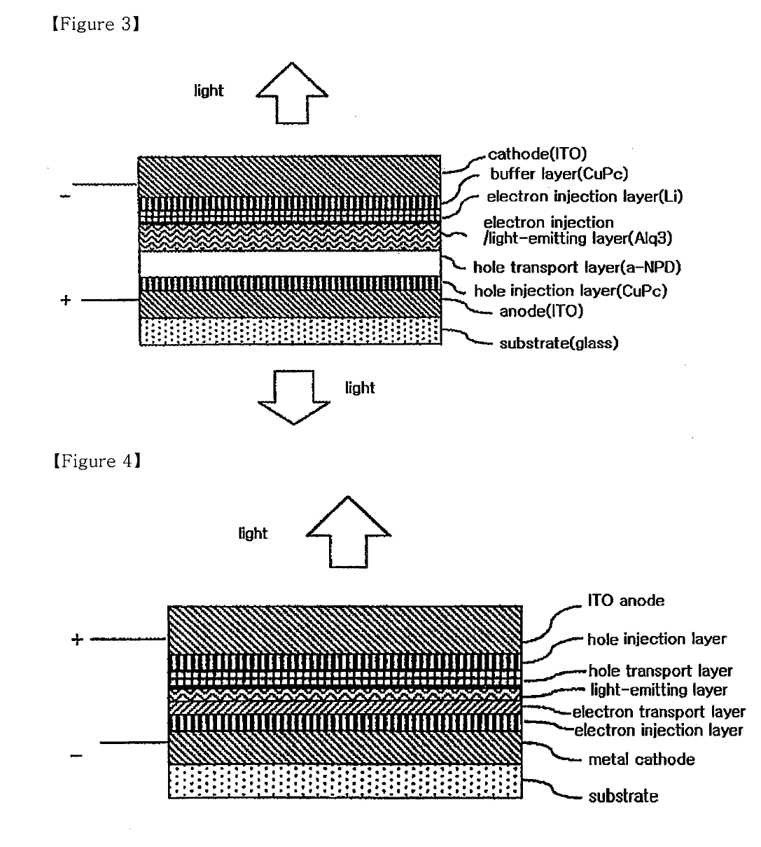

### BEST MODE FOR CARRYING OUT THE INVENTION

Hereinafter, the present invention will be described in detail.

As a compound used in the above organic material layers, the compound of formula 1 is described in Korean Paten Laid-open Publication 2003-0067773 and the compound of formula 2 is described in U.S. Pat. No. 5,645,948. Preferred compound having an Imidazole group includes compounds having the following formulae:

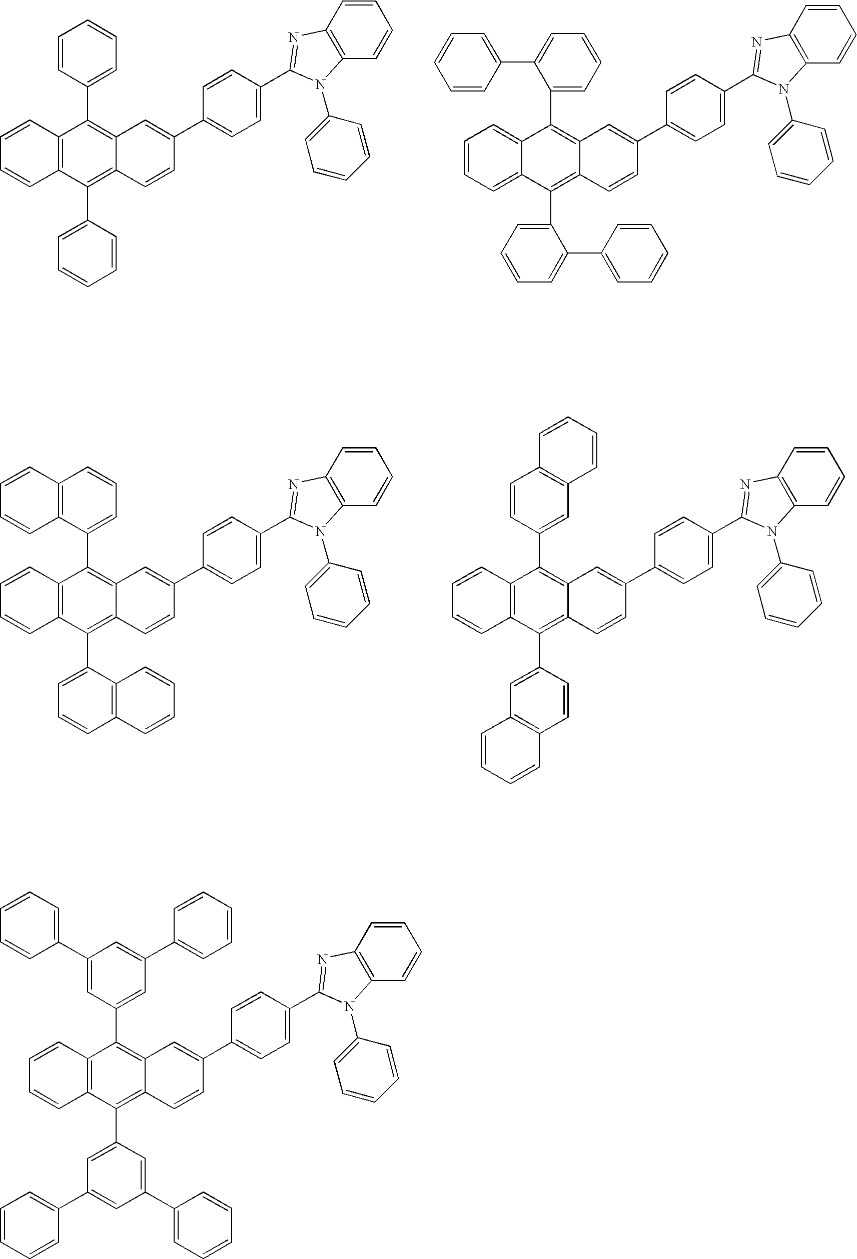

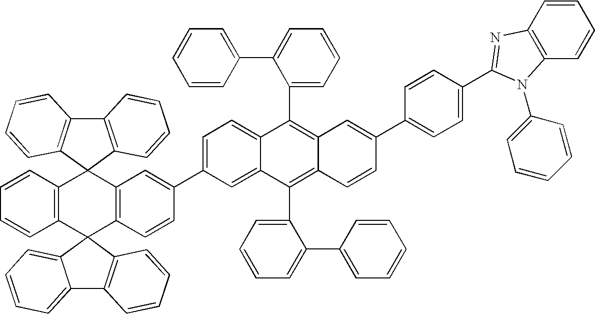

The organic material layer comprising a compound having a functional group selected from the group consisting of an imidazole group, an oxazole group and a thiazole group may be an electron transport layer and the electron transport layer can be formed by the co-deposition of an organic material with a metal having low work function, such as, Li, Cs, Na, Mg, Sc, Ca, K, Ce, Eu or a thin metal film containing at least one of these metals.

The organic electroluminescent device according to the present invention preferably comprises an electron injection layer with the organic material layer comprising a compound having a functional group selected from the group consisting of an imidazole group, an oxazole group and a thiazole group. A LiF layer is preferred as the electron injection layer.

The organic electroluminescent device according to the present invention is preferred to additionally comprise a buffer layer comprising the compound of the following formual 3 between the light-emitting layer and the anode:

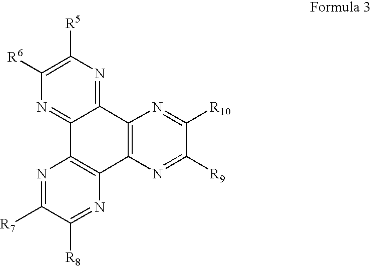

wherein, R⁵ to R¹⁰ are each respectively selected from the group consisting of hydrogen, halogen atoms, nitrile (—CN), nitro (—NO₂), sulfonyl (—SO₂R³¹), sulfoxide (—SOR³¹), sulfonamide (—SO₂NR³¹), sulfonate (—SO₃R³¹), trifluoromethyl (—CF₃), ester (—COOR³¹), amide (—CONHR³¹ or —CONR³¹R³²), substituted or unsubstituted straight or branched C₁-C₁₂ alkoxy, substituted or unsubstituted straight or branched C₁-C₁₂ alkyl, substituted or unsubstituted aromatic or non-aromatic heterocyclic rings, substituted or unsubstituted aryl, substituted or unsubstituted mono- or di-arylamine, and substituted or unsubstituted aralkylamine, and R³¹ and R³² are each respectively selected from the group consisting of substituted or unsubstituted C₁-C₆₀ alkyl, substituted or unsubstituted aryl, and substituted or unsubstituted 5- to 7-membered heterocyclic rings.

Preferred examples of the compound of formula 1 include compounds represented by the following formulae 3-1 to 3-6:

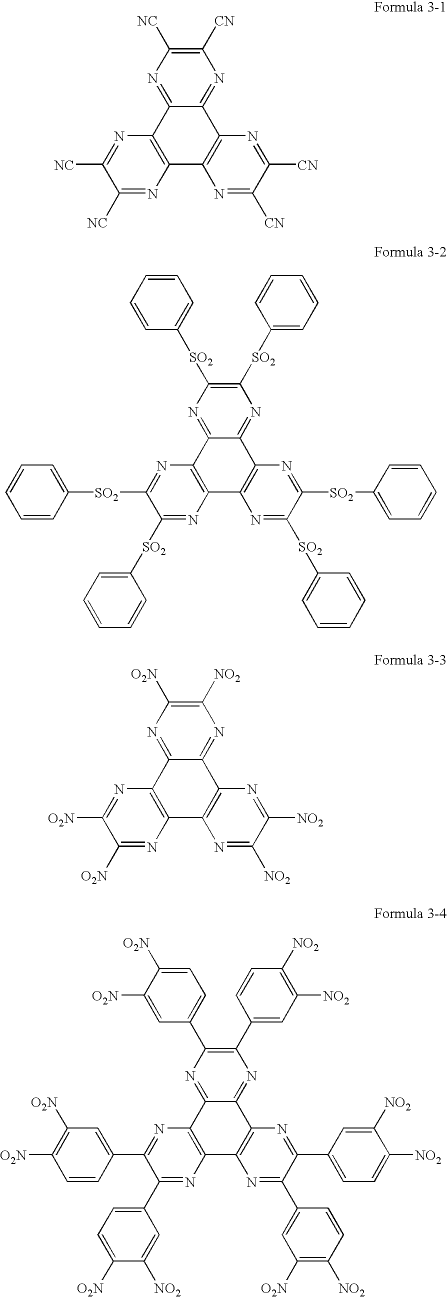

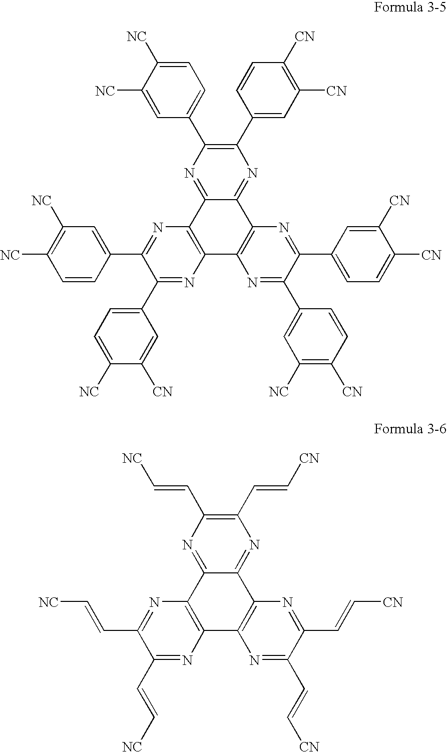

Other examples, synthetic methods and various features of the compound of formula 3 are described in the US patent application No. 2002-0158242, U.S. Pat. No. 6,436,559 and U.S. Pat. No. 4,780,536, the disclosures of which are all incorporated herein by reference.

The buffer layer comprising the compound of the formula 3 is preferred to be formed to be in contact with the anode.

The buffer layer comprising the compound of formula 3 can prevent the organic material layer in contact with the anode from being damaged when forming the anode on the organic material layer during the process of fabricating the organic electroluminescent device. For example, if a technique, such as sputtering, is used for the formation of the anode, particularly a transparent anode, on the light-emitting layer, hole transport layer or hole injection layer, electrical or physical damage to the organic material layer can occur due to electrically charged particles or atoms having high kinetic energy, which are generated in plasma during a sputtering process. This damage to the organic material layer can likewise occur when forming an electrode on the organic material layer not only by sputtering but also by thin-film formation technology capable of causing damage to the organic material layer by involving charges or particles having high kinetic energy. However, when the anode is formed on the buffer layer comprising the compound of formula 3 using the above-described method, electrical or physical damage to the organic material layer can be minimized or prevented. This can be attributed to the fact that the compound of formula 3 has a higher crystallinity than that of organic materials used in the prior organic electroluminescent devices, so that the organic material layer comprising the compound has a higher density.

In the organic electroluminescent device according to the present invention, because it is possible to prevent damage to the organic material layer in a process of forming the anode, the control of process parameters and the optimization of a process apparatus during the formation of the anode becomes easier, so that process productivity throughout can also be improved. Also, the material and deposition method of the anode can be selected from a wide range thereof. For example, in addition to a transparent electrode such as IZO (indium doped zinc-oxide) or ITO (indium doped tinoxide), a thin film made of metal, such as Al, Ag, Au, Ni, Pd, Ti, Mo, Mg, Ca, Zn, Te, Pt, Ir or an alloy material containing at least one of these metals can also be formed by sputtering or by physical vapor deposition (PVD) using laser, ion-beam assisted deposition or similar technologies which can cause damage to the organic material layer in the absence of the buffer comprising the compound of formula 3 by involving charges or particles having high kinetic energy.

In the organic electroluminescent device according to the present invention, the anode is preferred to consist of a metal or metal oxide having a work function of 2 to 6 eV, more preferably ITO or IZO.

In the present invention, the electrical properties of the organic electroluminescent device can be improved by the use of a buffer layer comprising the compound of formula 3. For example, the inventive organic electroluminescent device shows a reduction in leakage current in a reverse bias state, leading to a remarkable improvement in current-voltage characteristics, and thus, a very clear rectification characteristic. As used herein, the term “rectification characteristic,” which is a general characteristic of diodes means that the magnitude of current in a region applied with reverse voltage is much lower than the magnitude of current in a region applied with forward voltage. The compound of formula 3 has excellent crystallinity compared to organic materials, which have been used in the prior organic electroluminescent devices as described above so that a layer made of the compound of formula 3 has a high density. Thus, the compound of formula 3 effectively prevents structural defects of molecules or defects to interfacial characteristics, which occur when particles having high kinetic energy are implanted into the inside or interlayer interface of the organic material layer by a sputtering process or the like. For this reason, the electrical characteristics, such as rectification characteristic, of the device seem to be maintained.

Also, the buffer layer comprising the compound of formula 3 has higher visible ray permeability than an inorganic material layer used in the prior buffer layer that are made of, for example, metal or CuPc, so that its thickness is controlled more variably than the prior buffer layer. When the inorganic material layer which has been used as the buffer layer in the prior art is generally formed to a thickness of 200 nm, it has very low visible ray permeability, however, the layer comprising the compound of formula 3 did not show a reduction in visible ray permeability even when its thickness was 200 nm. In the present invention, the thickness of the buffer layer comprising the compound of formula 3 is preferably equal to or more than 20 nm, and more preferably equal to or more than 50 nm. If the thickness of the buffer layer is less than 20 nm, the layer cannot sufficiently function as the buffer layer. Meanwhile, the thickness of the buffer layer is preferred to be equal to or less than 250 nm. If the thickness of the buffer layer is more than 250 nm, the process time required for the fabrication of the device will become long and the surface shape of the organic material layer comprising the compound of formula 3 will become rough, thus adversely affecting the other characteristics of the device.

Furthermore, in the organic electroluminescent device according to the present invention, the buffer layer comprising the compound of formula 3 acts as a hole injection layer for injecting holes from the anode into a hole transport layer or a light-emitting layer or as a charge generation layer for forming hole-electron pairs. Accordingly, the inventive organic electroluminescent device can become more efficient without requiring a separate hole injection layer or hole transport layer.

In the present invention, a thin oxide film having an insulating property may be additionally formed between the anode and the buffer layer.

The organic electroluminescent device according to the present invention can be applied to a top emission structure or a both-side emission structure.

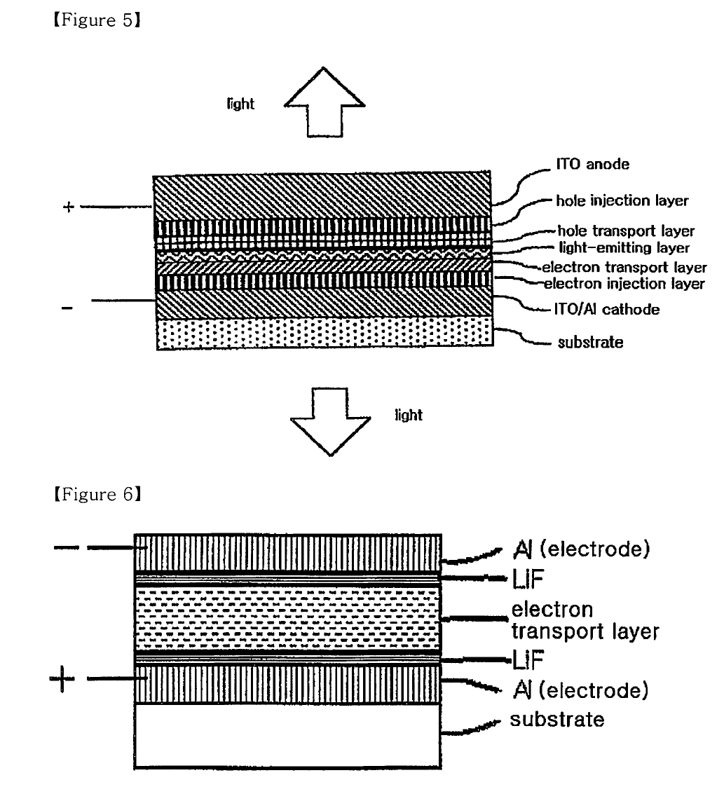

Examples of the organic electroluminescent device according to the present invention are shown in FIGS. 4 and 5. FIG. 4 illustrates a top emission type electroluminescent device, and FIG. 5 illustrates a both-side emission type electroluminescent device. However, it will be understood that the structure of the inventive organic electroluminescent device is not limited only to these structures.

The organic material layers in the inventive organic electroluminescent device may consist not only of the organic material layer comprising a compound having a functional group selected from the group consisting of an imidazole group, an oxazole group and a thiazole group and the light-emitting layer, but also, if necessary, of a multilayer structure comprising the buffer layer comprising the compound of Formula 3 and additional organic material layers. For example, the inventive organic electroluminescent device may have a structure comprising a hole injection layer, a hole transport layer, a hole injection/transport layer, a light-emitting layer, an electron transport layer, an electron injection layer, a buffer layer formed between an anode and the hole injection layer, and the like as organic material layers. However, the structure of the organic electroluminescent device is not limited only to this structure and may comprise a smaller number of organic material layers.

### Mode for the Invention

Hereinafter, the present invention will be described in detail using examples. It is to be understood, however, that these examples are given for illustrative purpose only and are not to be construed to limit the scope of the present invention.

### EXAMPLES

### Example 1

On a glass substrate, a cathode (Al) having a thickness of 150 nm and an electron injection layer (LiF) having a thickness of 1.5 nm were sequentially formed by a thermal evaporation process. Then, on the electron injection layer, an electron transport layer consisting of a thin film made of the material comprising imidazole group represented by the following formula 1-1 comprising an imidazole group was formed to a thickness of 150 nm.

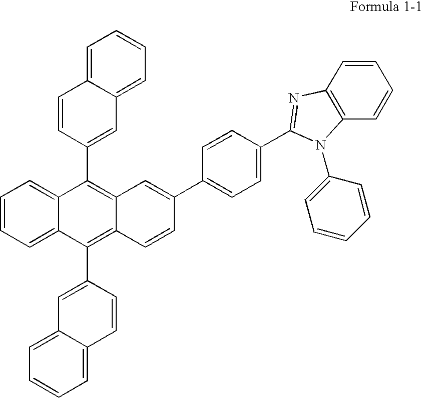

On the electron transport layer, an electron injection layer (LiF) having a thickness of 1.5 nm and Al layer having a thickness of 150 nm were formed sequentially to fabricate a symmetrical-type device as shown in FIG. 6 in which electric current runs only through electrons.

### Comparative Example 1

A symmetrical-type device, as shown in FIG. 6 in which electric current runs only through electrons, was fabricated in the same manner as described in Example 1, except that Alq3 in place of the compound comprising an imidazole group in Example 1.

The devices fabricated in Example 1 and Comparative Example 1 were symmetrical-type devices having the structure of Al-LiF-electron transport materialLiF-Al, in which the electric current running through the electron transport material is generated only by electrons.

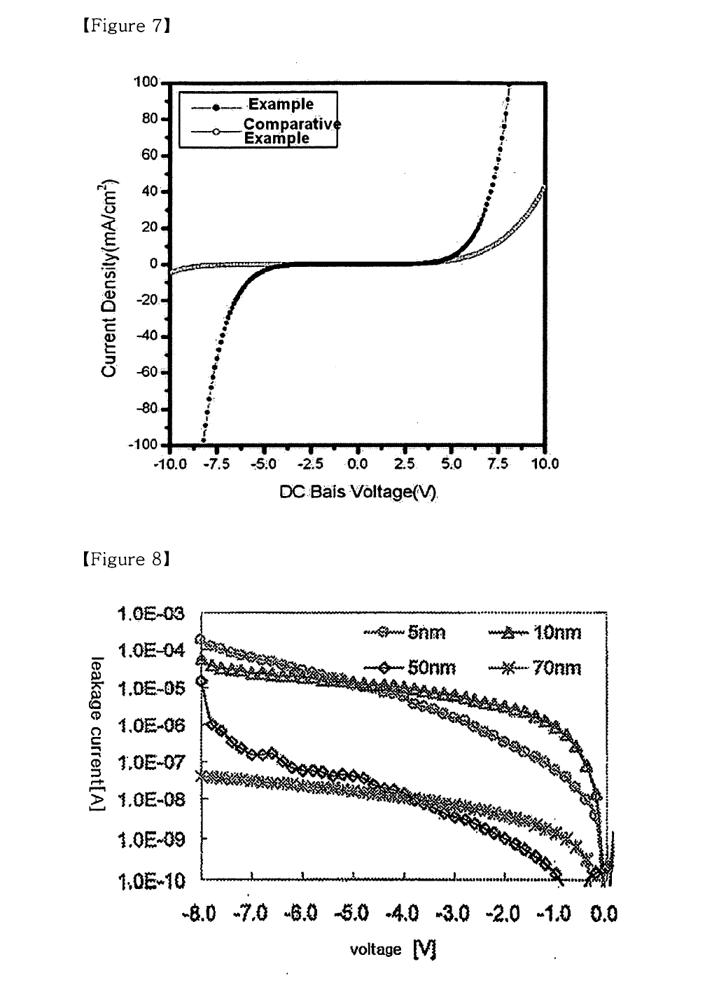

FIG. 7 shows current-voltage characteristic in Example 1 and Comparative Example 1. In FIG. 7, the positive voltage shows electron injection from top Al electrode to the electron transport layer and the negative voltage shows electron injection from bottom Al electrode to the electron transport layer. In Comparative Example 1 that used Alq3 which is frequently used in organic electroluminescent device as an electron transport material, electron injection from top Al electrode took place very well while electron injection from bottom Al electrode did not take place very well in spite of a symmetrical-type device. On the other hand, in Example 1 that used the compound comprising an imidazole group as an electron transport material, current voltage characteristic is symmetrical and this means that electron injection from both of top Al electrode and bottom Al electrode to the electron transport layer took place very well.

The reason that the electron injection from the bottom electrode to the electron transport layer took place more effectively through the compound comprising an imidazole group than Alq3 is considered as the reactivity of imidazole group in the compound of formula 1-1 to Li ion in Li-fluoride (LiF) is larger than that of Alq3. Accordingly, when a material having a group of a large reactivity to Li ion, such as, the imidazole group, is used as an electron transport material, electron injection characteristic from bottom electrode to electron transport layer can be improved.

The above results show that, if an electron transport material comprising an imidazole group, or an oxazole or thiazole group having similar properties to the imidazole group, as described above, is used, an organic electroluminescent device having improved electron injection characteristic can be provided, since an organic electroluminescent device having an inverted structure requires electron injection from bottom electrode to electron transport layer.

### Examples 2-6

Fabrication of Organic Electroluminescent Device

On a glass substrate, a cathode (Al) having a thickness of 150 nm and an electron injection layer (LiF) having a thickness of 1.5 nm were sequentially formed by a thermal evaporation process. Then, on the electron injection layer, an electron transport layer consisting of a thin film made of a material comprising an imidazole group used in Example 1 was formed to a thickness of 20 nm.

Then, on the electron transport layer, an Alq light-emitting host was co-deposited with C545T

(10-(2-benzothiazolyl)-1,1,7,7-tetramethyl-2,3,6,7-tetrahyro-1H,5H,11H-1)benzopyran o[6,7,8-ij]quinolizin-11-one) to form a light-emitting layer having a thickness of 30 nm. On the light-emitting layer, a hole transport layer consisting of a thin film made of NPB (4,4′-bis[N-(1-napthyl)-N-phenylamino]biphenyl) was deposited to a thickness of 40 nm. On the hole transport layer, a hole injection/buffer layer made of a compound (HAT) represented by the following formula 3-1 was formed to a thickness of 5 nm (Example 2), 10 nm (Example 3), 20 nm (Example 4), 50 nm (Example 5) or 70 nm (Example 6):

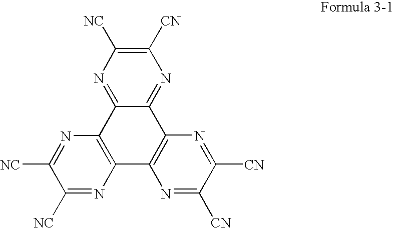

On the buffer layer, an IZO anode having a thickness of 150 nm was formed by a sputtering process at a rate of 1.3 Å/sec, thus fabricating a top emission type organic electroluminescent device.

### Example 7

Fabrication of Organic Electroluminescent Device

A both-side emission type organic electroluminescent device was fabricated in the same manner as described in Examples 2-6 except that a cathode consisting of a thin Al film having a very small thickness of 5 nm formed on an ITO film having a thickness of 150 nm is used in place of the cathode consisting of the thin Al film having a thickness of 150 nm.

[Measurement of Current-Voltage Characteristics and Light Emission Characteristics of Device]

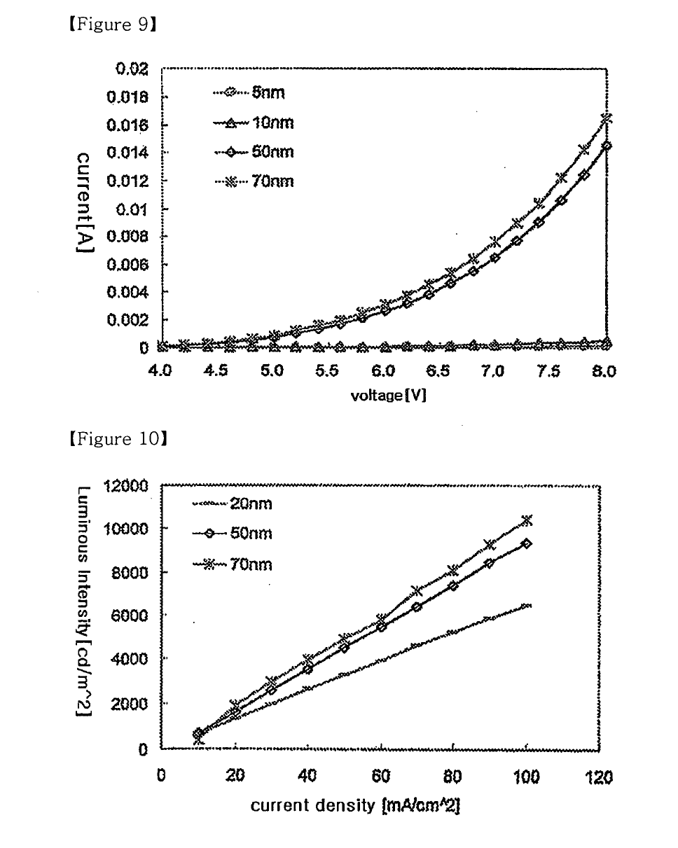

To the organic electroluminescent device fabricated in Examples 2-6, each of reverse and forward electric fields was applied at a voltage increasing at increments of 0.2 volts while current at each voltage value was measured. The measurement results are shown in FIGS. 8 and 9, respectively.

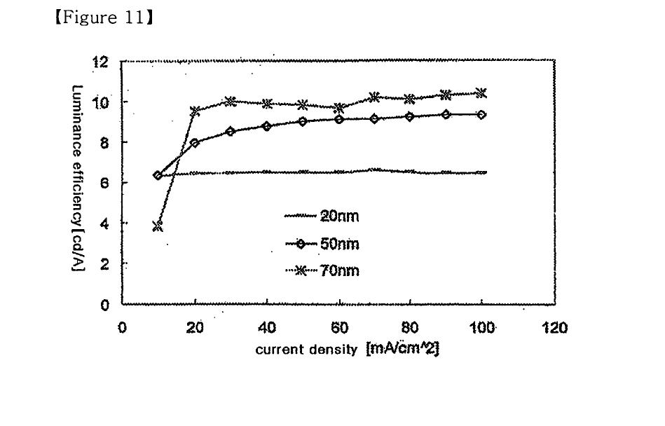

Also, to the organic electroluminescent device fabricated in Examples 4-6, current was applied while gradually increasing current density from 10 mA/cm² to 100 mA/cm², and at the same time, the luminous intensity of the device was measured using photometry. The measurement results are shown in FIGS. 10 and 11.

In organic electroluminescent devices, damage to an organic material layer occurring in the formation of an electrode leads to deterioration in current-voltage characteristics and light emission characteristics. Thus, the current-voltage characteristics and light emission characteristics shown in FIGS. 8 to 11 indicate that the compound of formula 3 has the effect of preventing damage to the organic material layer.

More particularly, FIGS. 8 and 9 show the current-voltage characteristics of the organic electroluminescent device as a function of the thickness of the inventive buffer layer. It is known that when an organic material layer in contact with the anode located opposite the substrate is made of an organic material, which has been generally used in the prior organic electroluminescent device, an organic electroluminescent device comprising this organic material layer will not show normal rectification and light emission characteristics due to the damage to the organic material layer, which occurs when forming the anode on the organic material layer by sputtering. However, as shown in FIGS. 8 and 9, the inherent characteristics (e.g., rectification characteristic) of the organic electroluminescent device were clearly shown as the thickness of the buffer layer made of the compound of formula 3 increased.

Regarding a reverse current-voltage characteristic shown in FIG. 8, the case of forming the buffer layer comprising the compound of Formula 3 to a thickness of about 5-10 nm showed little improvement in the leakage current of the device, and the case of forming the buffer layer to a thickness of more than 50 nm showed a remarkable improvement in the leakage current of the device, indicating a very clear rectification characteristic. Regarding a forward current-voltage characteristic shown in FIG. 9, when the thickness of the layer made of the compound of formula 3 was increased from 10 nm to 50 nm, current was consequently increased rapidly.

Furthermore, as shown in FIG. 10, a light emission characteristic was also improved in proportion to an increase in the current as described above. Regarding luminance efficiency shown in FIG. 11, an increase in the thickness of the buffer layer comprising the compound of formula 3 showed a remarkable increase in luminance efficiency. This is attributable to the effect of the buffer layer of preventing sputtering damage.

1. An organic electroluminescent device comprising a substrate, a cathode, at least two organic material layers comprising a light-emitting layer, and an anode in the sequentially laminated form, in which the organic material layers comprise an organic material layer comprising a compound having a functional group selected from the group consisting of an imidazole group, an oxazole group and a thiazole group between the cathode and the light-emitting layer.

2. The organic electroluminescent device of claim 1, wherein the compound having a functional group selected from the group consisting of an imidazole group, an oxazole group and a thiazole group includes a compound represented by the following formula 1 or 2: 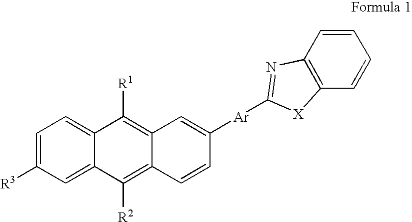
wherein, R¹ and R² may be the same or different from each other, and are each respectively selected from the group consisting of hydrogen, aliphatic hydrocarbons of 1-20 carbon atoms, aromatic rings and aromatic heterocyclic rings; Ar is selected from the group consisting of aromatic rings and aromatic heterocyclic rings; R³ is selected from the group consisting of hydrogen, aliphatic hydrocarbons having 1-6 carbon atoms, aromatic rings and aromatic heterocyclic rings; and X is selected from the group consisting of O, S and NR¹¹ wherein R¹¹ is selected from the group consisting of hydrogen, aliphatic hydrocarbons of 1-7 carbon atoms, aromatic rings and aromatic heterocyclic rings, provided that both of R¹ and R² are not hydrogen at the same time, and 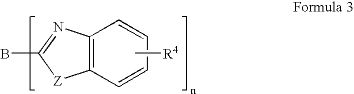
wherein Z is O, S or NR²²; R⁴ and R²² are respectively hydrogen, alkyl of 1-24 carbon atoms, aryl or hetero-atom substituted aryl of 5-20 carbon atoms, halogen atoms, or alkylene or alkylene comprising a hetero-atom necessary to complete a fused ring with a benzazole ring; B is a linkage unit consisting of alkylene, arylene, substituted alkylene, or substituted arylene, which conjugatedly or unconjugately connects the multiple benzazoles together; and n is an integer from 3 to 8.

3. The organic electroluminescent device of claim 1, wherein the organic material layer comprising a compound having a functional group selected from the group consisting of an imidazole group, an oxazole group and a thiazole group is an electron transport layer.

4. The organic electroluminescent device of claim 1, additionally comprising a buffer layer comprising a compound represented by the following formula 3 between the light-emitting layer and the anode: 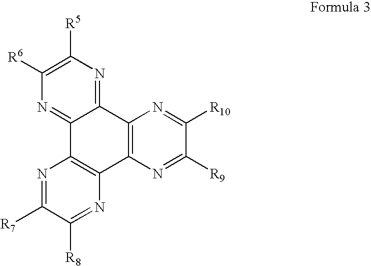
wherein, R⁵ to R¹⁰ are each respectively selected from the group consisting of hydrogen, halogen atoms, nitrile (—CN), nitro (—NO₂), sulfonyl (—SO₂R³¹), sulfoxide (—SOR³¹), sulfonamide (—SO₂NR³¹), sufonate (—SO₃R³¹), trifluoromethyl (—CF₃), ester (—COOR³¹), amide (—CONHR³¹ or —CONR³¹R³²), substituted or unsubstituted straight or branched C₁-C₁₂ alkoxy, substituted or unsubstituted straight or branched C₁-C₁₂ alkyl, substituted or unsubstituted aromatic or non-aromatic heterocyclic rings, substituted or unsubstituted aryl, substituted or unsubstituted mono- or di-arylamine, and substituted or unsubstituted aralkylamine, and R³¹ and R³² are each respectively selected from the group consisting of substituted or unsubstituted C₁-C₆₀ alkyl, substituted or unsubstituted ary, and substituted or unsubstituted 5- to 7-membered heterocyclic rings.

5. The organic electroluminescent device of claim 4, wherein the compound represented by the following formula 3 is selected from compounds represented by the following formulas 3-1 to 3-6:

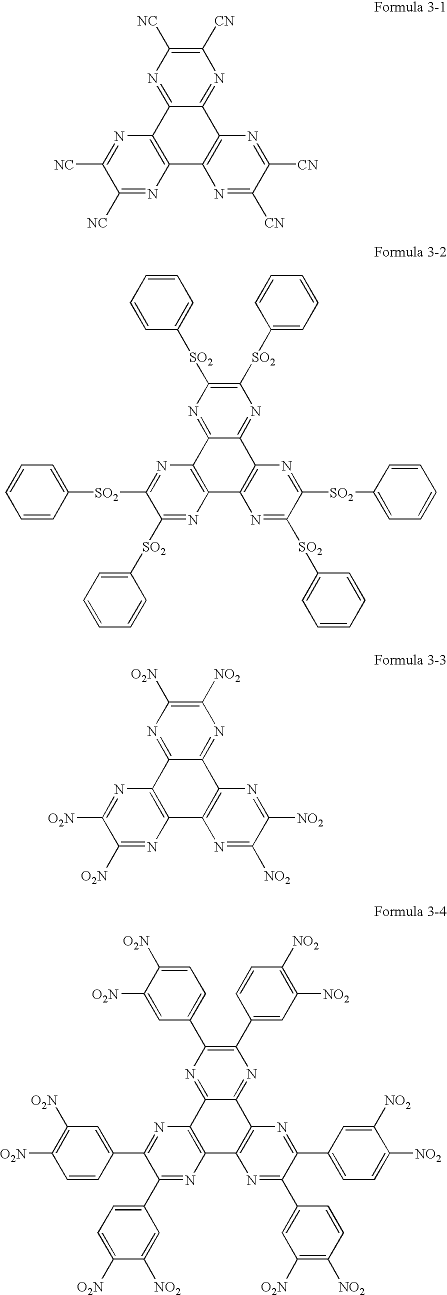

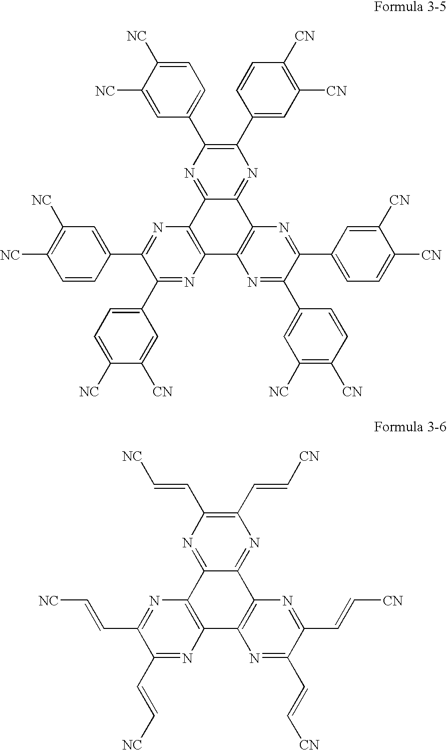

6. The organic electroluminescent device of claim 1, wherein the organic electroluminescent device is a top emission type or both-side emission type device.

7. The organic electroluminescent device of claim 4, wherein the organic electroluminescent device is a top emission type or both-side emission type device.

8. The organic electroluminescent device of claim 4, wherein the anode is formed by thin-film formation technology capable of causing damage to the organic material layer in contact with the anode by involving charges or particles with high kinetic energy.

9. The organic electroluminescent device of claim 8, wherein the thin-film formation technology is selected from the group consisting of sputtering, physical vapor deposition (PVD) using a laser, and ion-beam assisted deposition.

10. The organic electroluminescent device of claim 6, wherein the anode is made of a metal or metal oxide having work function of 2-6 eV.

11. The organic electroluminescent device of claim 10, wherein the anode is made of ITO or IZO.

12. The organic electroluminescent device of claim 4, wherein the buffer layer also serves as a hole injection layer.

13. The organic electroluminescent device of claim 4, wherein the buffer layer has a thickness of equal to or more than 20 nm.

14. The organic electroluminescent device of claim 4, wherein a thin oxide film having an insulating property is additionally formed between the anode and the buffer layer.

15. The organic electroluminescent device of claim 3, wherein an electron injection layer is formed between the cathode and the electron transport layer.

16. The organic electroluminescent device of claim 15, wherein the electron injection layer is a LiF layer.

17. The organic electroluminescent device of claim 1, additionally comprising a hole injection layer, a hole transport layer, or a hole injection and transport layer between the light-emitting layer and the anode.

18. A method for fabricating an organic electroluminescent device, comprising the step of sequentially laminating a cathode, an organic material layer comprising a compound having a functional group selected from the group consisting of an imidazole group, an oxazole group and a thiazole group, a light-emitting layer and an anode on a substrate.

19. The method for fabricating an organic electroluminescent device of claim 18, wherein the compound having a functional group selected from the group consisting of an imidazole group, an oxazole group and a thiazole group includes a compound represented by the following formula 1 or 2: 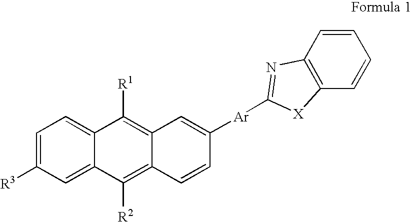
wherein, R¹ and R² may be the same or different from each other, and are each respectively selected from the group consisting of hydrogen, aliphatic hydrocarbons of 1-20 carbon atoms, aromatic rings and aromatic heterocyclic rings; Ar is selected from the group consisting of aromatic rings and aromatic heterocyclic rings; R³ is selected from the group consisting of hydrogen, aliphatic hydrocarbons having 1-6 carbon atoms, aromatic rings and aromatic heterocyclic rings; and X is selected from the group consisting of O, S and NR¹¹ wherein R¹¹ is selected from the group consisting of hydrogen, aliphatic hydrocarbons of 1-7 carbon atoms, aromatic rings and aromatic heterocyclic rings, provided that both of R¹ and R² are not hydrogen at the same time, and 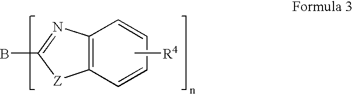
wherein Z is O, S or NR²²; R⁴ and R²² are respectively hydrogen, alkyl of 1-24 carbon atoms, aryl or hetero-atom substituted aryl of 5-20 carbon atoms, halogen atoms, or alkylene or alkylene comprising a hetero-atom necessary to complete a fused ring with a benzazole ring; B is a linkage unit consisting of alkylene, arylene, substituted alkylene, or substituted arylene, which conjugatedly or unconjugately connects the multiple benzazoles together; and n is an integer from 3 to 8.

20. The method for fabricating an organic electroluminescent device of claim 18, wherein additionally comprising the step of forming a buffer layer comprising a compound represented by the following formula 3 between the light-emitting layer and the anode: 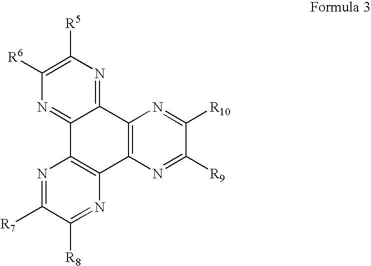
wherein, R⁵ to R¹⁰ are each respectively selected from the group consisting of hydrogen, halogen atoms, nitrile (—CN), nitro (—NO₂), sulfonyl (—SO₃R³¹), sulfoxide (—SOR³¹), sulfonamide (—SO₂NR³¹), sulfonate (—SO₃R³²), trifluoromethyl (—CF₃), ester (—COOR³¹), amide (—CONHR³¹ or —CONR³¹R³²), substituted or unsubstituted straight or branched C₁-C₁₂ alkoxy, substituted or unsubstituted straight or branched C₁-C₁₂ alkyl, substituted or unsubstituted aromatic or non-aromatic heterocyclic rings, substituted or unsubstituted aryl, substituted or unsubstituted mono- or di-arylamine, and substituted or unsubstituted aralkylamine, and R³¹ and R³² are each respectively selected from the group consisting of substituted or unsubstituted C₁-C₆₀ alkyl, substituted or unsubstituted aryl, and substituted or unsubstituted 5- to 7-membered heterocyclic rings.

21. The method for fabricating an organic electroluminescent device of claim 20, wherein the anode is formed by thin-film formation technology capable of causing damage to the organic material layer in contact with the anode by involving charges or particles having high kinetic energy.
